(19) United States
(12) Patent Application Publication
(10) Pub. No.: US 2011/0098849 A1
(43) Pub. Date: Apr. 28, 2011

(54) ALL-IN-ONE DOOR SWITCH INTERFACE TO MULTIPLE CONTROLLERS WITHIN A VENDING MACHINE

(75) Inventors: Scott Hudis, Stillwater, MN (US); David Rogers, Round Rock, TX (US)

(73) Assignee: CRANE MERCHANDISING SYSTEMS, INC., Bridgeton, MO (US)

(21) Appl. No.: 12/912,486

(22) Filed: Oct. 26, 2010

Related U.S. Application Data
(60) Provisional application No. 61/279,892, filed on Oct. 26, 2009.

(51) Int. Cl. G06F 17/00; H03K 5/22

(52) U.S. Cl. 700/232; 327/90

(57) ABSTRACT

A vending machine door switch interface allows multiple controllers, including the vending machine controller, to employ a single door switch without polarization or interference. The interface includes a comparator having inputs coupled across the door switch and, based on the door switch state, produces an output signal indicating whether the service door is closed or open. The comparator output when the service door is known to be open is recorded to subsequently distinguish open and closed states. Unbalanced connections to power and ground result in different voltages at the comparator inputs when the door switch is closed.

### PRIORITY CLAIM

This application claims the benefit of the filing date of U.S. Provisional Patent Application Ser. No. 61/279,892 filed Oct. 26, 2009, which is hereby incorporated by reference.

### TECHNICAL FIELD

The present application relates generally to door switches indicating the state of a vending machine service door and, more specifically, to an interface allowing multiple controllers within the vending machine to employ a single door switch.

### BACKGROUND

Vending machines are typically equipped with a service door normally used by the vending machine operator to stock the vending machine, program or retrieve data from the vending machine, and/or load or unload currency or coins within the vending machine payment system. Often a door switch within the vending machine indicates the state (i.e., “open” or “closed”) of the service door.

Attempts to interface multiple controllers to a single service door switch may result in the door switch signal electronics becoming polarized by at least one of the controllers, resulting in unreliable operation. There is, therefore, a need in the art for an interface providing reliable operation of multiple controllers within a vending machine based upon signals from a single door switch.

### SUMMARY

A vending machine door switch interface allows multiple controllers, including the vending machine controller, to employ a single door switch without polarization or interference. The interface includes a comparator having inputs coupled across the door switch and, based on the door switch state, produces an output signal indicating whether the service door is closed or open. The comparator output when the service door is known to be open is recorded to subsequently distinguish open and closed states. Unbalanced connections to power and ground result in different voltages at the comparator inputs when the door switch is closed.

Before undertaking the DETAILED DESCRIPTION below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, such a device may be implemented in hardware, firmware or software, or some combination of at least two of the same. It should be noted that the functionality associated with any particular controller may be centralized or distributed, whether locally or remotely. Definitions for certain words and phrases are provided throughout this patent document, those of ordinary skill in the art should understand that in many, if not most instances, such definitions apply to prior, as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 is a simplified perspective view illustrating a vending machine including multiple controllers, a single service door switch, and an interface between the controllers and the door switch according to one embodiment of the present disclosure;

FIG. 2 is a block diagram of selected electrical and electro-mechanical components within the vending machine of FIG. 1;

FIG. 3 is a circuit diagram for one implementation of a door switch interface between a single service door switch and multiple controllers within the vending machine of FIG. 1 according to one embodiment of the present disclosure; and

FIG. 4 is a high level flow chart for a process of calibrating the output of a door switch interface between a single service door switch and multiple controllers within the vending machine of FIG. 1 according to one embodiment of the present disclosure.

### DETAILED DESCRIPTION

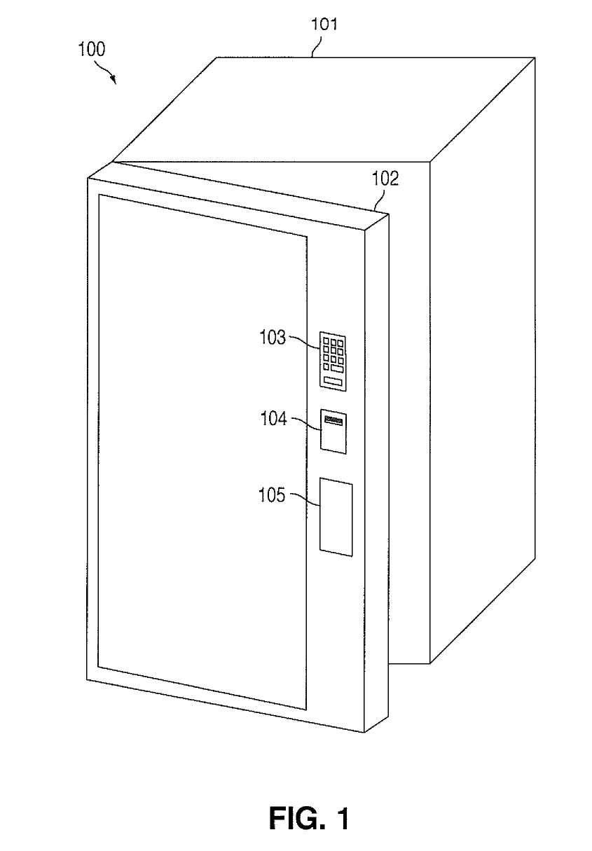

FIGS. 1 through 4, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged vending machine.

FIG. 1 is a simplified perspective view illustrating a vending machine 100 including multiple controllers, a single service door switch, and an interface between the controllers and the door switch according to one embodiment of the present disclosure. Vending machine 100 includes a cabinet 101 and a service door 102 that, together, define an enclosure. In the exemplary embodiment illustrated, the service door 102 is pivotally mounted to the front of the cabinet 101 and extends all the way across the front face of the vending machine 100. In alternate designs, the service door may extend only part way across the front of the vending machine, or may be formed in two portions (of equal or unequal sizes) that swing open in opposite directions.

In the exemplary embodiment illustrated in FIG. 1, the service door 102 includes a customer user interface 103, illustrated as a keypad and light emitting diode (LED) display or liquid crystal display (LCD). However, the customer user interface 103 may also employ a touchpad input device in addition to or in lieu of the keypad. Similarly, a payment system 104 is mounted within the service door 102 and includes one or more of a bill validator, a coin acceptor and/or a credit or debit card payment processing device. The payment system 104 receives currency, coins or other forms of payment from the customer and returns change as necessary. Finally, FIG. 1 depicts an access port 104 to a delivery receptacle mounted within the service door 102 or in the cabinet 101. The access port 104 may have a delivery door or other mechanical system (e.g., rotatable delivery receptacle open on one side) for controlling or restricting access by the customer into the delivery receptacle, the interior of the vending machine, or both. Those skilled in the art will recognize that in some vending machines, particularly helical coil snack vending machines, the access port 104 may be located near the bottom of the vending machine and extend across most of the width of the machine, below a large glass window allowing the contents within the cabinet to be viewed or a large liquid crystal display selectively presenting images of products available for vending or advertisements. Other vending machines, such as beverage vending machines having X-Y product retrieval and delivery mechanisms, may likewise have a glass front or large liquid crystal display, but may include an access port 104 to the side as shown in FIG. 1, at a height convenient to the customer for product retrieval without bending over.

In accordance with the known art, the service door 102 is held closed by a locking mechanical latch mechanism (not shown in FIG. 1), such as a T handle lock or an electronic lock. Some mechanical portions of a door switch (also not shown in FIG. 1) are often implemented in connection with such latch mechanism, and indicates the state of the service door 102 as either “open” or “closed.” Alternatively, mechanical portions of the door switch may instead be implemented separately from the locking mechanism.

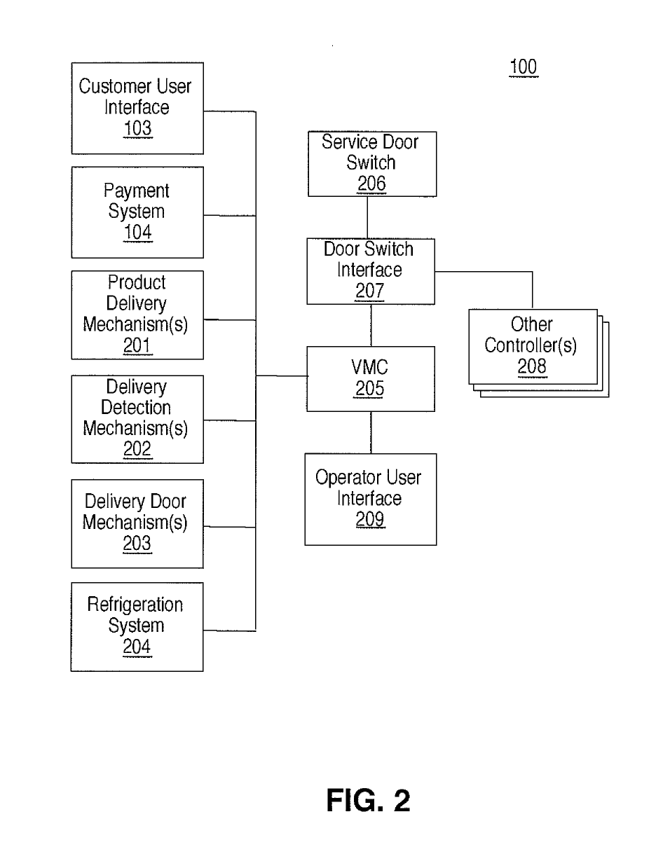

FIG. 2 is a block diagram of selected electrical and electro-mechanical components of the vending machine 100 of FIG. 1. Vending machine 100 includes electronics associated with the customer user interface 103 and the payment system 104. In addition, vending machine 100 includes mechanical, electrical and electronic systems for: product delivery mechanisms 201, such as vend motors driving helical coils or X-Y product retrieval and delivery devices; delivery detection mechanisms 202, such as optical sensors or contact sensors detecting passage of a vended article during delivery and/or presence of an article within the capture mechanism or the delivery receptacle; delivery door mechanisms 203 selectively opening or unlocking a delivery door over the access port 105; and an optional refrigeration system 204.

Many functions within vending machine 100 are controlled by a single vending machine controller (or “VMC”) 205. The VMC 205 is a programmable controller that is coupled to the customer user interface 103, the payment system 104, the product delivery mechanisms 201, the delivery detection mechanisms 202, the delivery door mechanisms 203 and/or the refrigeration system 204. By way of example, the vending machine controller 205 may enable selection of certain products in response to signals from the payment system 104, then actuate the appropriate product delivery mechanism(s) 201 to cause delivery of a selected product based upon the customer's input to customer user interface 103, open or unlock the delivery door mechanism(s) 203 to enable customer retrieval of the vended product, and finally cause the payment system 104 to cancel credit and/or issue change to the customer in response to detecting product delivery using the delivery detection mechanism(s) 202. VMC 205 thus interfaces with many different systems within the vending machine 101.

Vending machine 100 also includes an operator user interface 209 including at least one physical switch inside the vending machine 100, where it can only be actuated with the service door 102 open. Operator user interface 209 is coupled to VMC 205.

Although illustrated in FIG. 2 as a single set of connectors, the connections between VMC 205 and other components depicted in FIG. 2 may actually be implemented as more than one bus (each being either a stand-alone bus or a multi-drop bus) between the VMC 205 and the other components. In addition, the operator user interface 209 need not be connected directly to the VMC 205 as shown, but may instead be coupled to a common bus with other components depicted in FIG. 2.

Vending machine 100 also includes a service door switch 206 coupled to at least the VMC 205. Service door switch 206 is implemented using any of the known vending machine door switch structures and supplies a signal to VMC 205 indicating whether the service door 103 is open or closed. VMC 205 controls various functions within vending machine 100 based on the state of, or based on a change in the state of, the service door 102, as such state or change in state is indicated by door switch 206. For example, access to programming menus through the vending machine external customer user interface 103 may be enabled only when the service door 102 is open. The vending machine refrigeration system 204 (if any) may be automatically turned on when the door switch 206 output indicates that the service door 102 has been closed, from a previously open state, in order to compensate for temperature changes expected to be associated with opening the service door. Similarly, self-diagnostic routines may be triggered by detecting, based on the door switch 102, that the service door has been closed, from an open state.

As vending machines become more sophisticated, it is desirable to add functionality without overloading the VMC 205. Many sub-systems that can be added to the vending machine 101 can operate using one or more controller(s) 208 separate from the VMC 205, functioning largely independently from the remainder of the systems in vending machine 101 or in conjunction with specific components. For example, a large liquid crystal display (LCD) on the front exterior of the service door 102 may have a separate controller for generating the image(s) displayed, and changing the displayed image in response to specific events. The display controller (e.g., one of controller(s) 208) for the LCD may, when no customer is seeking to purchase products, display or cycle through a series of advertisements designed to attract customer attention to the products in the vending machine 101, or to promote goods or services unrelated to vending machine 101. In response to a customer initiating a purchase transaction (by using a user interface input to inquire as to products available or by depositing money), the display controller may switch to an image showing the products available for purchase and the quantity remaining within each product column, emulating a glass front vending machine. Alternatively, a telemetry controller (e.g., another of controller(s) 208) for wireless communication of sales information, inventory counts, bill or coin counts within a recycler for the payment system, etc. may operate substantially independently from the VMC 205, other than retrieving needed data from VMC 205 for transmission. As still another example, a payment systems controller (e.g., yet another of controller(s) 208) may be integrated into any of a bill validator, a coin acceptor or a credit/debit card swipe mechanism within payment system 104, to control or alter the manner in which change is dispensed following a customer purchase.

Such separate controllers 208 may operate differently depending on whether the service door 102 is open or closed, or may take action upon the door being opened or closed. For example, the display controller discussed above may blank the screen while the service door is open, the telemetry controller may report door opening events to a remote operations center, and the payment systems controller might initiate an electronic or printed report of the contents of the bill validator and/or coin acceptor.

As discussed above, attempts to interface multiple controllers to a single service door switch may result in the door switch signal electronics becoming polarized by at least one of the controllers, resulting in unreliable operation. One solution is to add a separate door switch. However, such redundancy adds additional mechanical complexity and expense to the construction and operation of the vending machine 101, and constitutes an additional point of potential failure. It would be preferable to allow all controller(s) 208, as well as VMC 205, to operate based on the signals from a single door switch 206. An interface 207 between the controller(s) 208 and door switch 206 preferably avoids polarization or incorrect polarity, shorts to the power rails, or other incorrect operation of door switch 206 when multiple controllers are coupled thereto.

Those skilled in the art will recognize that the full structure and operation of the vending machine 100 and each of the components thereof have not been depicted in FIGS. 1 and 2, or described in complete detail above. Instead, for simplicity and clarity, only so much of the vending machine that either differs from the structure and operation of known vending machines and their constituent components or is necessary for an understanding of the principles disclosed herein is depicted and described. Nonetheless, the vending machine and its components have known structure(s) associated therewith. In addition, various processes described in this disclosure are performed in connection with the vending machine 100, including processes that are executed by control circuitry (at least one controller operable to execute programmable instructions) and that executes operations and/or operates on data stored in, retrieved from and/or written to a memory device (at least one memory operable to store instructions and/or data) within the vending machine. The memory may be part of or coupled to the vending machine controller 205 or other controllers within the vending machine 100.

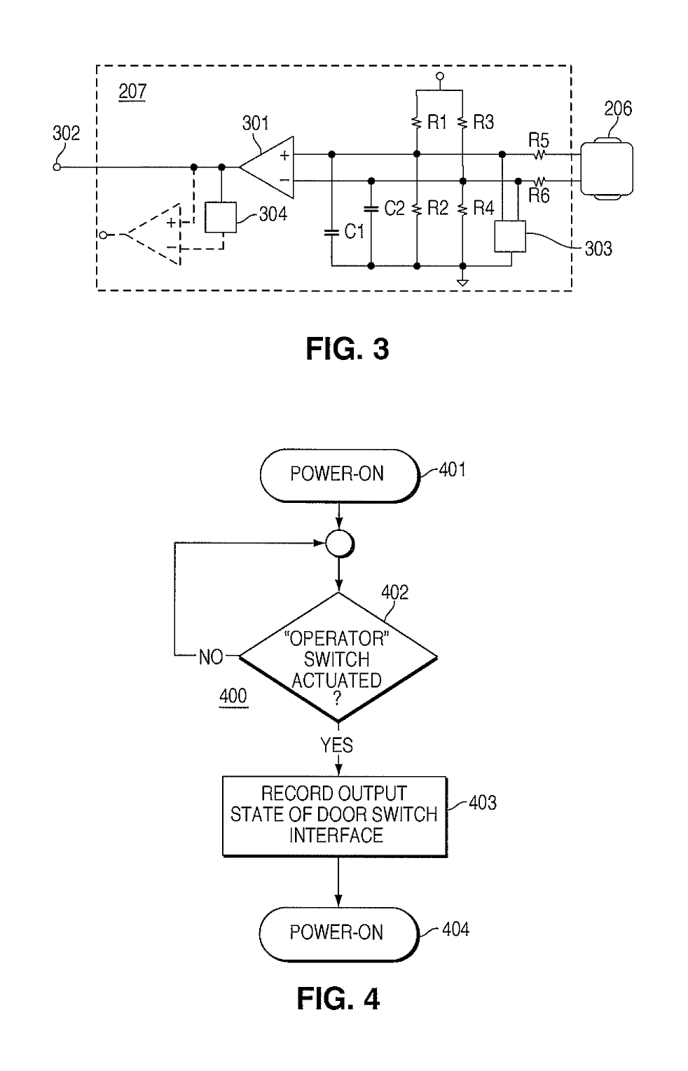

FIG. 3 is a circuit diagram for one implementation of a door switch interface 207 between a single service door switch and multiple controllers within the vending machine of FIG. 1 according to one embodiment of the present disclosure. It should be noted that the example of FIG. 3 is not intended to be limiting of a door switch interface in accordance with the present disclosure.

Door switch interface 207 in the example of FIG. 3 is implemented by a differential comparator 301 connected across the terminals (i.e., connected to both signal lines) of the door switch 206. Capacitors C1 and C2 couple the non-inverting or positive (“+”) and inverting or negative (“−”) comparator inputs, respectively, to ground. Both capacitors C1 and C2 have a value of approximately 0.1 micro-Farads (μF) in the exemplary embodiment. Resistors R1 and R2 couple the positive comparator input to a power supply voltage (e.g., 3 V or 5 V) and to ground, respectively, and both have values of approximately 100 kilo-Ohms (KΩ) in the exemplary embodiment. Resistors R3 and R4 couple the negative comparator input to the power supply voltage and to ground, respectively, and have values of approximately 100 KΩ and 90 KΩ, respectively. Resistor R5 is connected in series between one contact of the service door switch 206 and the positive comparator input, while resistor R6 is connected in series between the other contact of the service door switch 206 and the negative comparator input. Both resistors R5 and R6 have values of approximately 10 KΩ in the exemplary embodiment. Overvoltage protection 303 (e.g., Zener diodes) is coupled between ground and terminals of resistors R5 and R6 opposite the contacts of service door switch 207.

In many door switch signal electronics implementations, one of the signal lines will be connected to a power supply (e.g., a 5 volt power supply) and the other will be connected to ground. Instead of looking across a dry switch contact, in the exemplary door switch interface 207 the signal lines tie one differential comparator input to the comparator 301 to a known high or low state, with the other differential input being drawn toward the same level when the service door switch 206 is closed and pulled in the other direction when the service door switch is open. That is, if the positive input of the comparator is connected to the power supply line and the negative input is connected to ground, when the service door switch 206 is closed, either the positive input of the comparator will be pulled toward ground or the negative input will be pulled toward the power supply voltage. The output 302 of comparator 301 signals the state of service door switch 206 to controller(s) 208 coupled thereto by, for example, direct connection, buffers/inverters, and/or other signal conditioning electronics such as amplifiers.

Resistor R4 has a value different than that from resistors R1, R2 and R3. Thus, if service door switch 206 is a dry contact switch, the differential inputs to comparator 301 are slightly unbalanced. When the service door switch 206 is open, the inverting comparator input is low compared to the non-inverting comparator input, allowing the detection of switch closure by differences in the output 302 of comparator 301 when service door 206 is open versus when service door 206 is closed.

Some vending machine door switch implementations pulse or scan the service door switch 206. Such pulsing has no effect on the exemplary door switch interface 207 since, when the service door switch 206 is closed, the pulsing is simply ignored. When the service door switch 206 is open, the pulsing is filtered by controller(s) 208 or, in an alternate embodiment, by a filter (not shown) such as a secondary comparator stage at the comparator output 302. In any event, the output 302 of comparator 301 will differ when the service door 206 is open and when service door 206 is closed, and such difference may be relied upon to identify the state of the service door 206.

FIG. 4 is a high level flow chart for a process of calibrating the output of a door switch interface 207 between a single service door switch and multiple controllers within the vending machine of FIG. 1 according to one embodiment of the present disclosure. Regardless of whether service door switch 206 is operated as a dry contact switch or pulsed, the switch may be wired either normally-open (NO) or normally-closed (NC). Accordingly, the state of the service door switch 206 must be correlated (or calibrated) to the state of the service door 102. The output of comparator 301 must be programmable to accurately indicate the state of the service door 102 based on the signal across service door switch 206.

The process 400 begins when the vending machine is powered on (step 401), either for the first time following delivery by the manufacturer or following a power-down cycle during normal operation. Logically the service door 102 must be open in order for one or more physical switches inside the vending machine 100 (e.g., operator programming switches, as part of operator user interface 209) to be actuated. Therefore, in the exemplary embodiment, when one of the physical switches accessible only inside the vending machine 100 (i.e., with the service door open) is actuated (step 402), the state of the output of door switch interface 207 is recorded (step 403) within a memory-type device 304 such as a register, a latch or a flip-flop. That state is subsequently used as indicative of the state of service door switch 206 when the service door is open. Optionally, the state of service door switch 206 that is recorded as indicating that the service door 102 is open is updated each time one of the physical switches inside the vending machine 100 is actuated. The memory-type device 304 may be directly accessible to controller(s) 208 (and VMC 205). Alternatively, an optional second comparator stage (shown in phantom in FIG. 3) may compare the state of output 302 with the state recorded within memory-type device 304, and output the result of that comparison to controller(s) 208 and/or VMC 205.

The door switch interface 207 described above is inexpensive to implement and replaces the need for separate door switch(es) to be provided for controller(s) other than the VMC. Multiple controllers, including the VMC, may be coupled to a single door switch.

Although the present disclosure has been described with exemplary embodiments, various changes and modifications may be suggested to one skilled in the art. It is intended that the present disclosure encompass such changes and modifications as fall within the scope of the appended claims.

What is claimed is:

1. A vending machine door switch interface comprising:
power supply voltage and ground voltage connections;
an output connection coupled to a plurality of controllers within a vending machine; and
a comparator having first and second inputs coupled across terminals for a door switch for a service door within the vending machine, wherein the door switch is in a first state when the service door is closed and in a second state when the service door is open,
wherein the first comparator input is coupled to the power supply voltage connection and the second comparator input is coupled to the ground voltage connection, and
wherein the door switch interface is configured to produce an output signal on the output connection based upon an output of the comparator, the output signal having a first value when the door switch is in the first state and a second value when the door switch is in the second state.

2. The vending machine door switch interface of claim 1, wherein a voltage at one of the first and second comparator inputs is tied to one of the power supply voltage and the ground voltage, and wherein a voltage at the other of the first and second comparator inputs is pulled toward the one of the power supply voltage and the ground voltage when the door switch is in a closed state and is pulled toward the other of the power supply voltage and the ground voltage when the door switch is in an open state.

3. The vending machine door switch interface of claim 1, wherein the coupling between the first comparator input and the power supply voltage and the coupling between the second comparator input and the ground voltage are unbalanced so that a voltage at one of the first and second comparator inputs is lower than a voltage at the other of the first and second comparator inputs when the door switch is in a closed state.

4. The vending machine door switch interface of claim 1, further comprising:
a first resistor connecting the first comparator input to the power supply voltage connection;
a second resistor connecting the first comparator input to the ground voltage connection;
a third resistor connecting the second comparator input to the power supply voltage connection; and
a fourth resistor connecting the second comparator input to the ground voltage connection,
wherein the first, second and third resistors have approximately the same resistance while the fourth resistor has a resistance different from the resistance of the first, second and third resistors.

5. The vending machine door switch interface of claim 4, further comprising:
a fifth resistor connecting the first comparator input to a first door switch terminal connection; and
a sixth resistor connecting the second comparator input to a second door switch terminal connection.

6. The vending machine door switch interface of claim 5, further comprising:
first and second capacitors connecting the first and second comparator inputs, respectively, to the ground voltage connection.

7. The vending machine door switch interface of claim 6, further comprising:
one or more overvoltage protection devices connecting the first and second comparator inputs to the ground voltage connection.

8. The vending machine door switch interface of claim 1, further comprising:
a memory type device coupled to the comparator output, the memory type device storing a value of the output signal when the service door is in a known one of an open state and a closed state.

9. A vending machine including the vending machine door switch interface of claim 1, the vending machine further comprising:
a chassis;
the service door mounted to the chassis;
the door switch mounted to one of the chassis and the service door; and
the plurality of controllers, including a vending machine controller and at least one other controller, connected to the output connection.

10. The vending machine of claim 9, wherein the at least one other controller comprises one or more of:
a display controller;
a telemetry controller; and
a payment systems controller.

11. A method of detecting the state of a vending machine door, the method comprising:
supplying power to a vending machine having
an output connection for a door switch interface connected to a plurality of controllers within the vending machine, and
first and second inputs for a comparator coupled across terminals for a door switch for a service door within the vending machine, wherein the door switch is in a first state when the service door is closed and in a second state when the service door is open,
the first comparator input coupled to a power supply voltage connection,
the second comparator input coupled to a ground voltage connection; and
producing an output signal on the output connection based upon an output of the comparator, the output signal having a first value when the door switch is in the first state and a second value when the door switch is in the second state.

12. The method of claim 11, wherein a voltage at one of the first and second comparator inputs is tied to one of the power supply voltage and the ground voltage, and wherein a voltage at the other of the first and second comparator inputs is pulled toward the one of the power supply voltage and the ground voltage when the door switch is in a closed state and is pulled toward the other of the power supply voltage and the ground voltage when the door switch is in an open state.

13. The method of claim 11, wherein the coupling between the first comparator input and the power supply voltage and the coupling between the second comparator input and the ground voltage are unbalanced so that a voltage at one of the first and second comparator inputs is lower than a voltage at the other of the first and second comparator inputs when the door switch is in a closed state.

14. The method of claim 11, wherein a first resistor connects the first comparator input to the power supply voltage connection, a second resistor connects the first comparator input to the ground voltage connection, a third resistor connects the second comparator input to the power supply voltage connection, and a fourth resistor connects the second comparator input to the ground voltage connection, and
wherein the first, second and third resistors have approximately the same resistance while the fourth resistor has a resistance different from the resistance of the first, second and third resistors.

15. The method of claim 14, wherein a fifth resistor connects the first comparator input to a first door switch terminal connection and a sixth resistor connects the second comparator input to a second door switch terminal connection.

16. The method of claim 15, wherein first and second capacitors connecting the first and second comparator inputs, respectively, to the ground voltage connection.

17. The method of claim 16, wherein one or more overvoltage protection devices connect the first and second comparator inputs to the ground voltage connection.

18. The method of claim 11, further comprising:
storing a value of the output signal within a memory type device coupled to the comparator output when the service door is in a known one of an open state and a closed state.

19. A method of claim 11, further comprising:
transmitting the output signal to each of the plurality of controllers, the plurality of controllers including a vending machine controller and at least one other controller.

20. The method of claim 19, further comprising transmitting the output signal to each of one or more of:
a display controller;
a telemetry controller; and
a payment systems controller.
